(19) United States
(12) Patent Application Publication
(10) Pub. No.: US 2025/0079393 A1
(43) Pub. Date: Mar. 6, 2025

(54) SEMICONDUCTOR PACKAGE AND METHOD FOR FABRICATING THE SAME

(71) Applicant: SAMSUNG ELECTRONICS CO., LTD., SUWON-SI (KR)

(72) Inventors: Sang Cheon PARK, Suwon-si (KR); Un-Byoung KANG, Suwon-si (KR); Ku Young KIM, Suwon-si (KR); Jun Woo MYUNG, Suwon-si (KR); Seung-Jin LEE, Suwon-si (KR); Ji-Seok HONG, Suwon-si (KR)

(21) Appl. No.: 18/748,354

(22) Filed: Jun. 20, 2024

(30) Foreign Application Priority Data
Sep. 1, 2023 (KR) 10-2023-0116304
Feb. 6, 2024 (KR) 10-2024-0018360

(51) Int. Cl. H01L 23/00; H01L 23/28; H01L 23/48; H01L 23/498; H01L 25/065; H10B 80/00

(52) U.S. Cl. CPC H01L 24/80; H01L 23/481; H01L 24/08; H01L 24/97; H01L 25/0657; H01L 23/28; H01L 23/49816; H01L 2224/08146; H01L 2224/80986; H01L 2224/97; H01L 2225/06555; H10B 80/00

(57) ABSTRACT

A semiconductor package includes: a first semiconductor chip including a first substrate and a first through electrode passing through the first substrate, wherein the first substrate has a first active surface and a first non-active surface; a chip structure including a plurality of second semiconductor chips stacked on the first semiconductor chip, wherein each second semiconductor chip includes a second substrate and a second through electrode passing through the second substrate; and a third semiconductor chip disposed on the chip structure, and including a third substrate, wherein the first substrate has a first width and a first thickness, wherein the second substrate has a second width and a second thickness, and the third substrate has a third width and a third thickness, wherein the third thickness is thicker than the second thickness, and the third width is greater than the second width.

### CROSS-REFERENCE TO RELATED APPLICATION

This application claims priority under 35 USC § 119 to Korean Patent Application No. 10-2023-0116304, filed on Sep. 1, 2023, and No. 10-2024-0018360, filed on Feb. 6, 2024, in the Korean Intellectual Property Office, the disclosures of which are incorporated by reference herein in their entireties.

### TECHNICAL FIELD

Embodiments of the present inventive concept relate to a semiconductor package and a method for fabricating the same.

### DISCUSSION OF THE RELATED ART

With the demand for miniaturization, large capacity and high performance of electronic devices increasing, demand for high integration and high speed semiconductor packages has also been increasing. To this end, a semiconductor package, which includes a plurality of semiconductor chips that are stacked, has been under development.

For example, when a plurality of semiconductor chips are stacked on a wafer, copper pads of semiconductor chips facing each other may be bonded to each other by using hybrid bonding technology. However, void defects may occur between the stacked semiconductor chips due to a step difference that may be on a surface of the wafer.

### SUMMARY

According to an embodiment of the present inventive concept, a semiconductor package includes: a first semiconductor chip including a first substrate and a first through electrode passing through the first substrate, wherein the first substrate has a first active surface and a first non-active surface; a chip structure including a plurality of second semiconductor chips stacked on the first semiconductor chip, wherein each second semiconductor chip includes a second substrate and a second through electrode passing through the second substrate, wherein the second substrate has a second active surface and a second non-active surface; and a third semiconductor chip disposed on the chip structure, and including a third substrate having a third active surface and a third non-active surface, wherein the first substrate has a first width and a first thickness, wherein the second substrate has a second width and a second thickness, and the third substrate has a third width and a third thickness, wherein the third thickness is thicker than the second thickness, and the third width is greater than the second width.

According to an embodiment of the present inventive concept, a semiconductor package includes: a first semiconductor chip including a first substrate, which has a first active surface and a first non-active surface, a first through electrode passing through the first substrate, a first chip pad disposed on the first active surface, a second chip disposed on the first non-active surface, and a first insulating layer at least partially surrounding a periphery of the second chip pad, wherein the first chip pad and the second chip pad are connected to each other through the first through electrode; a chip structure including a plurality of second semiconductor chips stacked on the first semiconductor chip, wherein each second semiconductor chip includes a second substrate, which has a second active surface and a second non-active surface, a second through electrode passing through the second substrate, a third chip pad disposed on the second active surface, a fourth chip pad disposed on the second non-active surface, a second insulating layer at least partially surrounding a periphery of the third chip pad, and a third insulating layer at least partially surround a periphery of the fourth chip pad, wherein the third chip and the fourth chip pad are electrically connected to the second through electrode; and a third semiconductor chip disposed on the chip structure, and including a third substrate, which has a third active surface and a third non-active surface, a fifth chip pad disposed on the third active surface, and a fourth insulating layer at least partially surrounding a periphery of the third chip pad, wherein the third chip pad of a second semiconductor chip, of the plurality of second semiconductor chips, disposed at a lowermost side of the chip structure and the second chip pad of the first semiconductor chip are coupled to each other, and a second insulating layer of the second semiconductor chip that is disposed at the lowermost side of the chip structure and the first insulating layer of the first semiconductor chip are coupled to each other, wherein a third chip pad of a second semiconductor chip, of the plurality of second semiconductor chips, that is disposed at an uppermost side of the chip structure and the fourth chip pad of the third semiconductor chip are coupled to each other, and a third insulating layer of the second semiconductor chip that is disposed at the uppermost side of the chip structure and the fourth insulating layer of the third semiconductor chip are coupled to each other, wherein the first substrate has a first width and a first thickness, wherein the second substrate has a second width and a second thickness, and the third substrate has a third width and a third thickness, wherein the third thickness is thicker than the second thickness, and the third width is greater than the second width, and the third thickness is thicker than the first thickness, and the third width is smaller than the first width.

According to an embodiment of the present inventive concept, a method for fabricating a semiconductor package includes: preparing a first structure including a third semiconductor chip and a plurality of second semiconductor chips stacked on the third semiconductor chip; bonding a plurality of the first structures, which are spaced apart from each other, onto a bottom wafer; and forming a plurality of semiconductor packages by cutting the bottom wafer for each of the plurality of first structures, wherein each of the plurality of semiconductor packages includes a first semiconductor chip, the plurality of second semiconductor chips stacked on the first semiconductor chip, and the third semiconductor chip stacked on the plurality of second semiconductor chips, and wherein the first semiconductor chip corresponds to the bottom wafer that is cut, wherein a first substrate of the first semiconductor chip has a first width and a first thickness, wherein a second substrate of each of the plurality of second semiconductor chips has a second width and a second thickness, and a third substrate of the third semiconductor chip has a third width and a third thickness, and the third thickness is thicker than the second thickness, and the third width is greater than the second width.

### BRIEF DESCRIPTION OF THE DRAWINGS

The above and other aspects and features of the present inventive concept will become more apparent by describing in detail example embodiments thereof with reference to the attached drawings, in which:

FIG. 1 is a cross-sectional view illustrating a semiconductor package according to embodiments of the present inventive concept;

FIG. 2 is a cross-sectional view illustrating a semiconductor package according to embodiments of the present inventive concept;

FIG. 3 is a cross-sectional view illustrating a semiconductor package according to embodiments of the present inventive concept;

FIG. 4 is a flow chart illustrating a method for fabricating a semiconductor package according to embodiments of the present inventive concept;

FIGS. 5, 6, 7, 8, 9, 10 and 11 are views illustrating intermediate steps to describe the method of FIG. 4; and

FIG. 12 is a view illustrating intermediate steps to describe a method for fabricating a semiconductor package according to embodiments of the present inventive concept.

### DETAILED DESCRIPTION OF THE DISCLOSURE

Hereinafter, embodiments of the present inventive concept will be described in detail with reference to the accompanying drawings. The same reference numerals will be used for the same elements in the drawings and specification, and a repeated description of the corresponding elements will be omitted or briefly discussed.

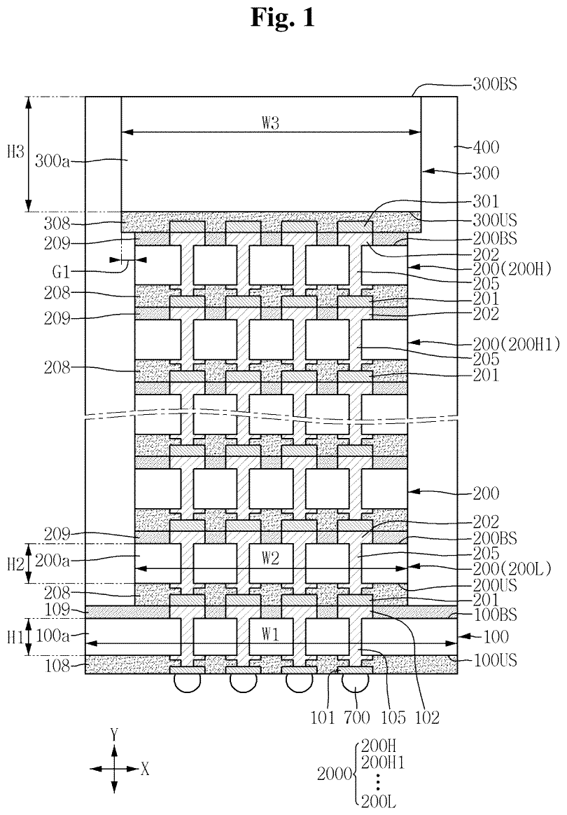

FIG. 1 is a cross-sectional view illustrating a semiconductor package according to embodiments of the present inventive concept.

Referring to FIG. 1, the semiconductor package according to embodiments of the present inventive concept includes a first semiconductor chip 100, a second semiconductor chip 200, a third semiconductor chip 300, and a mold layer 400.

A plurality of second semiconductor chips 200 are sequentially stacked in a first direction (direction Y) on the first semiconductor chip 100 to form a chip structure 2000. As shown, the chip structure 2000 is disposed on the first semiconductor chip 100, and the third semiconductor chip 300 is disposed on the chip structure 2000.

The first semiconductor chip 100 includes a first substrate 100a having a first active surface 100US and a first non-active surface 100BS, and a first through electrode 105 passing through the first substrate 100a. A chip pad 101 is disposed on the first active surface 100US, and an insulating layer 108 surrounding the periphery of the chip pad 101 is disposed on the first active surface 100US. A chip pad 102 is disposed on the first non-active surface 100BS, and an insulating layer 109 surrounding the periphery of the chip pad 102 is disposed on the first non-active surface 100BS. The chip pad 101 of the first active surface 100US and the chip pad 102 of the first non-active surface 100BS are electrically connected to each other by the first through electrode 105.

A connection terminal 700 may be attached to the chip pad 101 that is disposed on the first active surface 100US. The connection terminal 700 may be, for example, a solder ball or a bump, but the present inventive concept is not limited thereto. A redistribution line may be installed in the insulating layer 108 that is disposed on the first active surface 100US, but the present inventive concept is not limited thereto.

The second semiconductor chip 200 is disposed on the first non-active surface 100BS of the first semiconductor chip 100.

The second semiconductor chip 200 includes a second substrate 200a having a second active surface 200US and a second non-active surface 200BS, and a second through electrode 205 passing through the second substrate 200a. A chip pad 201 is disposed on the second active surface 200US, and an insulating layer 208 surrounding the periphery of the chip pad 201 is disposed on the second active surface 200US. A chip pad 202 is disposed on the second non-active surface 200BS, and an insulating layer 209 surrounding the periphery of the chip pad 202 is disposed on the second non-active surface 200BS. The chip pad 201 of the second active surface 200US and the chip pad 202 of the second non-active surface 200BS are electrically connected to each other by the second through electrode 205. A wiring line may be installed in the insulating layer 208 that is disposed on the second active surface 200US, but the present inventive concept is not limited thereto.

Hereinafter, a reference numeral 200 is used when referring to the second semiconductor chip as a whole. The second semiconductor chip closest to the first semiconductor chip 100 in the chip structure 2000 is referred to as 200L. The second semiconductor chip closest to the third semiconductor chip 300 in the chip structure 2000 is referred to as 200H. The second semiconductor chip positioned directly below 200H in the chip structure 2000 is referred to as 200H1.

The chip pad 102 of the first semiconductor chip 100 and the chip pad 201 of the second semiconductor chip 200L disposed on a lowermost side of the chip structure 2000 may be coupled with each other. For example, the chip pad 102 of the first semiconductor chip 100 and the chip pad 201 of the second semiconductor chip 200L face each other and are in direct contact with each other. In addition, the insulating layer 109 of the first semiconductor chip 100 and the insulating layer 208 of the second semiconductor chip 200, which face each other, may be coupled to each other. For example, the insulating layer 109 and the insulating layer 208 may be in direct contact with each other. For example, the chip pads 102 and 201 and the insulating layers 109 and 208 may be coupled with each other by hybrid bonding. The hybrid bonding bonds an insulating material to another insulating material while bonding metals to each other by using heat treatment or the like.

In addition, the chip pad 202 of the second semiconductor chip (e.g., 200H1) and the chip pad 201 of another second semiconductor chip (e.g., 200H), which face each other in the first direction (direction Y), may be coupled with each other. For example, the chip pad 202 of the second semiconductor chip (e.g., 200H1) and the chip pad 201 of another second semiconductor chip (e.g., 200H) may be in direct contact with each other. In addition, the insulating layer 209 of the second semiconductor chip 200H1 and the insulating layer 208 of the second semiconductor chip 200H, which face each other, may be coupled with each other. For example, the insulating layer 209 of the second semiconductor chip 200H1 and the insulating layer 208 of the second semiconductor chip 200H may be in direct contact with each other. For example, the chip pads 202 and 201 and the insulating layers 209 and 208 may be coupled to each other by hybrid bonding.

The third semiconductor chip 300 is disposed on the second semiconductor chip (i.e., 200H) disposed on at uppermost side of the chip structure 2000.

The third semiconductor chip 300 includes a third substrate 300a having a third active surface 300US and a third non-active surface 300BS. A chip pad 301 is disposed on the third active surface 300US, and an insulating layer 308 surrounding the periphery of the chip pad 301 is disposed on the third active surface 300US. Since the third semiconductor chip 300 is a chip positioned on an uppermost end of the semiconductor package, a through electrode might not be disposed in the third substrate 300a.

The chip pad 202 of the second semiconductor chip (e.g., 200H) and the chip pad 301 of the third semiconductor chip 300, which face each other in the first direction (direction Y), may be coupled with each other. For example, the chip pad 202 of the second semiconductor chip (e.g., 200H) and the chip pad 301 of the third semiconductor chip 300 may be in direct contact with each other. In addition, the insulating layer 209 of the second semiconductor chip 200H and the insulating layer 308 of the third semiconductor chip 300, which face each other, may be coupled with each other. For example, the insulating layer 209 of the second semiconductor chip 200H and the insulating layer 308 of the third semiconductor chip 300 may be in direct contact with each other. For example, the chip pads 202 and 301 and the insulating layers 209 and 308 may be coupled to each other by hybrid bonding.

The mold layer 400 at least partially surrounds a side of the chip structure 2000 and a side of the third semiconductor chip 300. The mold layer 400 may include, for example, an epoxy mold compound (EMC), but the present inventive concept is not limited thereto. As shown, the mold layer 400 may expose a side of the first semiconductor chip 100 and an upper surface of the third semiconductor chip 300. A heat dissipation member may be attached to the upper surface of the third semiconductor chip 300 with a thermal interface material (TIM) interposed therebetween. In an embodiment of the present inventive concept, the mold layer 400 may also cover the upper surface of the third semiconductor chip 300.

In addition, the first substrate 100a of the first semiconductor chip 100 has a first width W1 and a first thickness H1. The second substrate 200a of the second semiconductor chip 200 has a second width W2 and a second thickness H2, and the third substrate 300a of the third semiconductor chip 300 has a third width W3 and a third thickness H3.

In this case, the third width W3 may be greater than the second width W2. For example, an edge of the third semiconductor chip 300 may protrude farther in a second direction (direction X) than a corresponding edge of the second semiconductor chip 200H that is disposed at the uppermost side of the chip structure 2000 (see reference numeral G1). The protruded length G1 may be, for example, about 20 μm or more.

In this case, both the second semiconductor chip 200 and the third semiconductor chip 300 may be memory chips. A scribe line region of the third semiconductor chip 300 may be wider than that of the second semiconductor chip 200. Due to this configuration, the edge of the third semiconductor chip 300 may have a shape that protrudes farther than the corresponding edge of the second semiconductor chip 200H that is disposed at the uppermost side of the chip structure 2000.

For example, the second semiconductor chip 200 may be a chip cut by a blade dicing manner, and the third semiconductor chip 300 may be a chip cut by a stealth dicing manner. The remaining scribe line region of the chip cut by the stealth dicing manner is larger than the remaining scribe line region of the chip cut by the blade dicing manner. Therefore, even though the second semiconductor chip 200 and the third semiconductor chip 300 are the same type of memory chip, a size of the third semiconductor chip 300 may be larger than that of the second semiconductor chip 200.

In addition, the third thickness H3 may be thicker than the second thickness H2. For example, the third thickness H3 may be about 150 μm or more. When the third substrate 300a of the third semiconductor chip 300 is silicon and the third thickness H3 is smaller than about 150 μm, plastic deformation may occur as the load is linearly increased. However, when the third thickness H3 is greater than or equal to about 150 μm, a fracture may occur as the load is linearly increased. For example, when the third thickness H3 is greater than or equal to about 150 μm, plastic deformation may hardly occur.

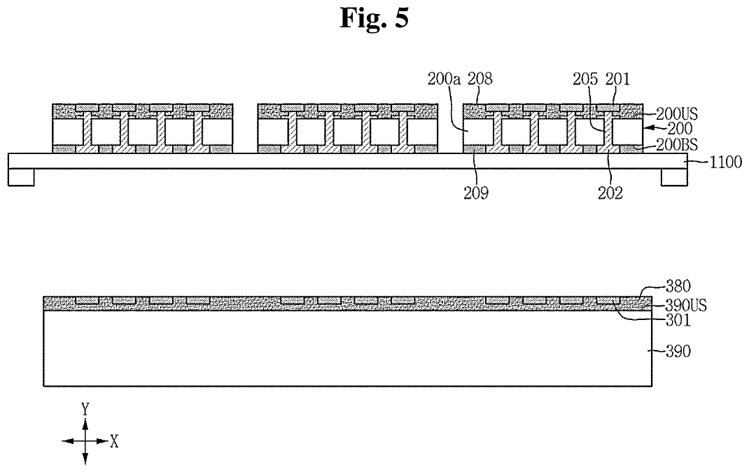

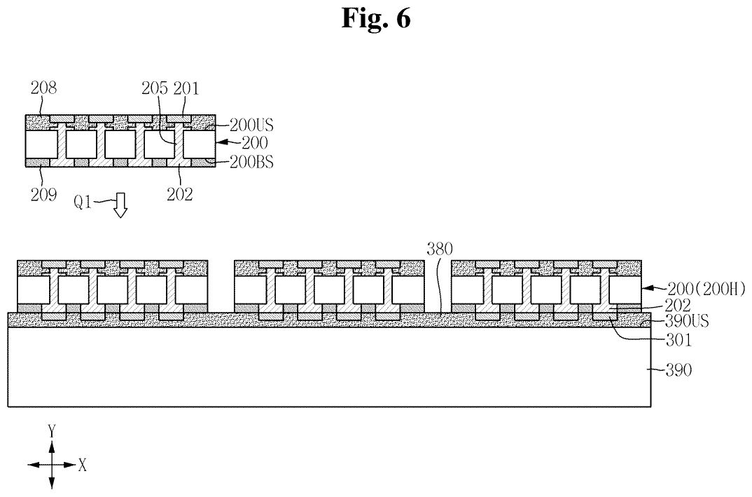

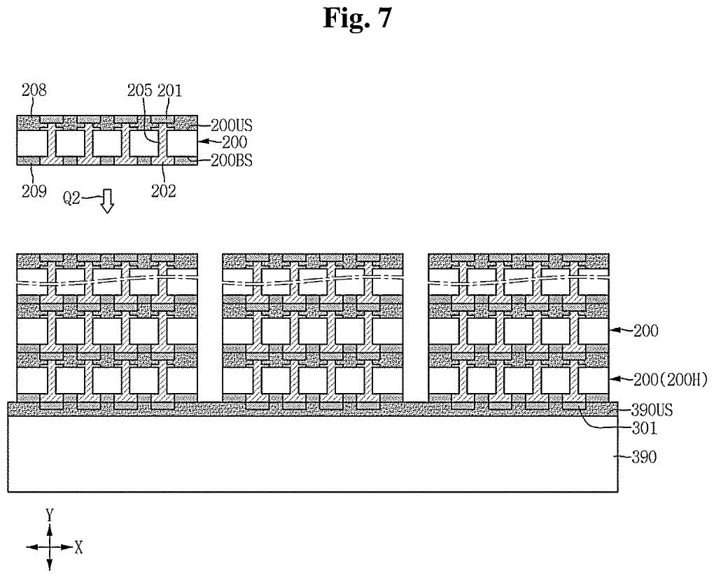

In addition, in embodiments of the present inventive concept, the reason why the size (e.g., width and thickness) of the third semiconductor chip 300 is larger than that of the second semiconductor chip 200 is to perform a process of sequentially stacking a plurality of second semiconductor chips 200 on the third semiconductor chip 300 (see FIGS. 5 to 7). As will be described later, since a plurality of second semiconductor chips 200 are stacked on the thick third semiconductor chip 300 instead of the thin first semiconductor chip 100 (see FIGS. 6 and 7), void defects due to a surface step difference during hybrid bonding may be minimized.

In embodiments of the present inventive concept, the first semiconductor chip 100 may be a logic chip, and the first semiconductor chip 100 may perform communication with the second semiconductor chip 200 and the third semiconductor chip 300, which are memory chips.

In embodiments of the present inventive concept, the second semiconductor chip 200 may be a memory chip, but the third semiconductor chip 300 may be a dummy chip rather than a memory chip.

In embodiments of the present inventive concept, the third thickness H3 may be thicker than the first thickness H1, and the third width W3 may be smaller than the first width W1.

In addition, the first active surface 100US of the first semiconductor chip 100, the second active surface 200US of the second semiconductor chip 200 and the third active surface 300US of the third semiconductor chip 300 are all directed to face downward with respect to the first direction (direction Y). The second active surface 200US and the third active surface 300US are directed to face toward the first semiconductor chip 100. For example, the first non-active surface 100BS of the first semiconductor chip 100 and the second active surface 200US of the second semiconductor chip 200L that is disposed at the lowermost side of the chip structure 2000 face each other. The third active surface 300US of the third semiconductor chip 300 and the second non-active surface 200BS of the second semiconductor chip 200H that is disposed at the uppermost side of the chip structure 2000 face each other.

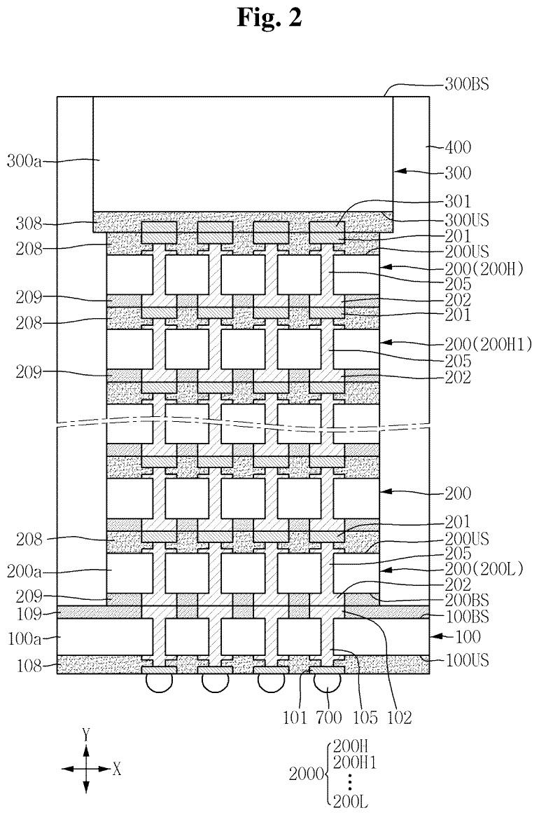

FIG. 2 is a cross-sectional view illustrating a semiconductor package according to embodiments of the present inventive concept. For convenience of description, the following description will be based on differences from the description made with reference to FIG. 1.

Referring to FIG. 2, the first active surface 100US of the first semiconductor chip 100 and the third active surface 300US of the third semiconductor chip 300 are directed to face downward with respect to the first direction (direction Y). The second active surfaces 200US of the plurality of second semiconductor chips 200 are directed to face upward with respect to the second direction (direction Y). For example, the first non-active surface 100BS of the first semiconductor chip 100 and the second non-active surface 200BS of the second semiconductor chip 200L that is disposed at the lowermost side of the chip structure 2000 face each other. The third active surface 300US of the third semiconductor chip 300 and the second active surface 200US of the second semiconductor chip 200H that is disposed at the uppermost side of the chip structure 2000 face each other.

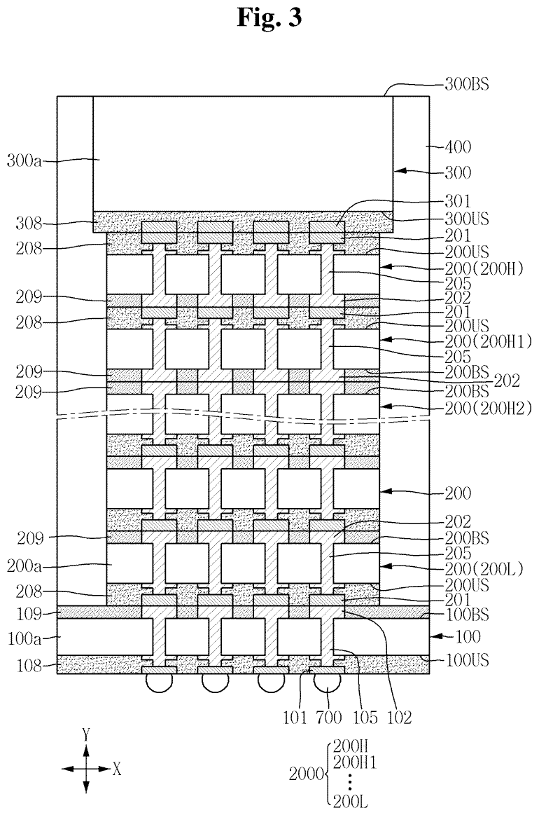

FIG. 3 is a cross-sectional view illustrating a semiconductor package according to embodiments of the present inventive concept. For convenience of description, the following description will be based on differences from the description made with reference to FIGS. 1 and 2.

Referring to FIG. 3, the first active surface 100US of the first semiconductor chip 100 and the third active surface 300US of the third semiconductor chip 300 are directed to face downward with respect to the first direction (direction Y).

The second active surfaces 200US of some of the second semiconductor chips (e.g., 200L and 200H2) of the chip structure 2000 are directed to face downward with respect to the second direction (direction Y), and the second active surfaces 200US of the remaining second semiconductor chips (e.g., 200H1 and 200H) are directed to face upward with respect to the second direction (direction Y). For example, second active surfaces 200US of lower second semiconductor chips (e.g., 200L and 200H2), which may be closer to the lowermost side of the chip structure 2000 than to the uppermost side of the chip structure 2000, may be directed to face downward with respect to the second direction (direction Y), and second active surfaces 200US of upper second semiconductor chips (e.g., 200H1 and 200H), which may be closer to the uppermost side of the chip structure 2000 than to the lowermost side of the chip structure 2000, may be directed to face upward with respect to the second direction (direction Y). For example, the first non-active surface 100BS of the first semiconductor chip 100 and the second active surface 200US of the second semiconductor chip 200L disposed at the lowermost side of the chip structure 2000 face each other. In the chip structure 2000, the second non-active surface 200BS of the second semiconductor chip 200H2, which is directed to face upward, and the second non-active surface 200BS of the second semiconductor chip H1, which is directed to face downward, face each other. The third active surface 300US of the third semiconductor chip 300 and the second active surface 200US of the second semiconductor chip 200H disposed at the uppermost side of the chip structure 2000 face each other.

In the chip structure 2000, the number of second semiconductor chips (e.g., 200L and 200H2) in which the second active surface 200US is directed to face downward may be greater than the number of second semiconductor chips (e.g., 200H1 and 200H2) in which the second active surface 200US is directed to face upward.

In addition, in embodiments of the present inventive concept, in the chip structure 2000, the number of second semiconductor chips (e.g., 200L and 200H2) in which the second active surface 200US is directed to face downward may be smaller than the number of second semiconductor chips (e.g., 200H1 and 200H) in which the second active surface 200US is directed to face upward.

In addition, in some embodiments of the present inventive concept, contrary to the shown example, the second active surfaces 200US of the second semiconductor chips (e.g., 200L and 200H2) may directed to face upward with respect to the second direction (direction Y), and the second active surfaces 200US of the remaining second semiconductor chips (e.g., 200H1 and 200H) may be directed to face downward with respect to the second direction (direction Y).

Hereinafter, a method for fabricating a semiconductor package according to embodiments of the present inventive concept will be described.

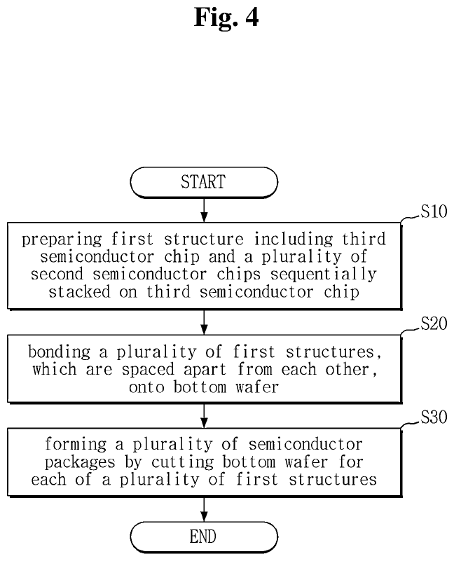

FIG. 4 is a flow chart illustrating a method for fabricating a semiconductor package according to embodiments of the present inventive concept. FIGS. 5 to 11 are views illustrating intermediate steps to describe the method of FIG. 4. For example, the method for fabricating a semiconductor package shown in FIG. I will be described.

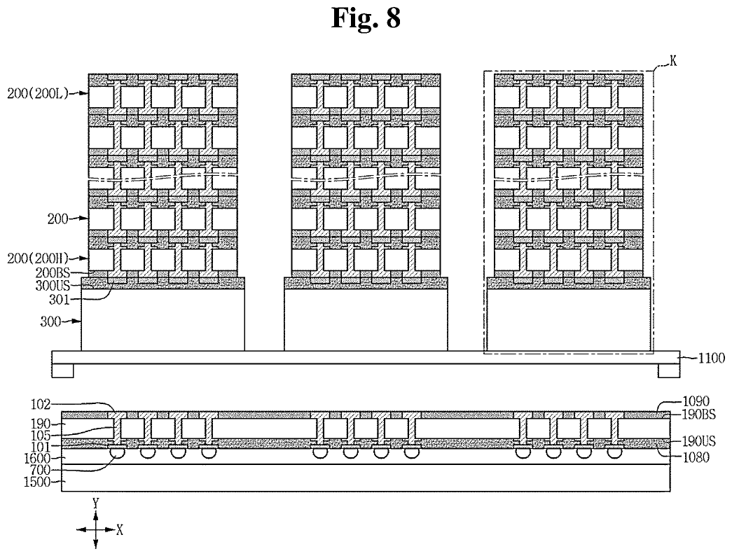

First, referring to FIG. 4, a first structure (see K of FIG. 8) including a third semiconductor chip 300 and a plurality of second semiconductor chips 200 sequentially stacked on the third semiconductor chip 300 is prepared (S10).

For example, referring to FIG. 5, an active surface 390US of a base wafer 390 faces upward in the first direction (direction Y). A plurality of chip pads 301 are disposed on the active surface 390US of the base wafer 390, and an insulating layer 380 is disposed adjacent to the chip pad 301. The base wafer 390 is then cut to become the third semiconductor chip 300.

In addition, a plurality of second semiconductor chips 200 are prepared on a support 1100. The second semiconductor chip 200 includes a second substrate 200a having a second active surface 200US and a second non-active surface 200BS, and a second through electrode 205 passing through the second substrate 200a. The chip pad 201 is disposed on the second active surface 200US, and the insulating layer 208 at least partially surrounding the periphery of the chip pad 201 is disposed on the second active surface 200US. The chip pad 202 is disposed on the second non-active surface 200BS, and the insulating layer 209 at least partially surrounding the periphery of the chip pad 202 is disposed on the second non-active surface 200BS. The chip pad 201 of the second active surface 200US and the chip pad 202 of the second non-active surface 200BS are electrically connected to each other by the second through electrode 205.

The second semiconductor chip 200 may be a memory chip. The second memory chip 200 may be, for example, a chip that is formed by cutting with a blade dicing manner. For example, a protective film is attached to one surface of the wafer, and a rear surface of the wafer is backgrounded. In addition, a dicing film is attached to the backgrounded rear surface of the wafer, and the protective film is removed. For example, then, the wafer is diced by using a blade.

Next, referring to FIG. 6, a plurality of second semiconductor chips 200 are disposed to be spaced apart from each other on the base wafer 390 (see reference number Q1).

In this case, the second non-active surface 200BS of the second semiconductor chip 200 is directed to face toward the active surface 390US of the base wafer 390. For example, by hybrid bonding, the chip pad 202 of the second semiconductor chip 200 and the chip pad 301 of the base wafer 390 are bonded to each other, and the insulating layer 209 of the second semiconductor chip 200 and the insulating layer 380 of the base wafer 390 are bonded to each other.

In this case, the second semiconductor chip (see 200H) disposed on the lowest portion on the base wafer 390 is disposed at an upper portion of the completed semiconductor package (see FIG. 1). For example, the second semiconductor chip 200H is the uppermost second semiconductor chip of the stacked plurality of second semiconductor chips 200.

Next, referring to FIG. 7, the second semiconductor chip 200 is additionally stacked on the plurality of second semiconductor chips 200 (see reference numeral Q2). The second non-active surface 200BS of the second semiconductor chip 200, which will be additionally stacked, is also stacked to face toward the active surface 390US of the base wafer 390.

Next, referring to FIG. 8, when a preset number of second semiconductor chips 200 are all stacked on the base wafer (390 of FIG. 7), the base wafer 390 is cut for each package to complete a first structure K. When the base wafer 390 is cut, for example, a stealth dicing manner may be used. For example, after the inside of the base wafer 390 is first cut by a laser, an external pressure may be applied to the wafer so that the chip may be separated from the base wafer 390. As a result of cutting the base wafer 390, the third semiconductor chip 300 is generated. The first structure K includes a third semiconductor chip 300 and a plurality of second semiconductor chips 200 sequentially stacked on the third semiconductor chip 300.

In addition, a bottom wafer 190 is prepared on a carrier substrate 1500. A plurality of chip pads 101 are disposed on the active surface 190US of the bottom wafer 190, and an insulating layer 1080 is disposed adjacent to the chip pad 101. A plurality of chip pads 102 are disposed on the non-active surface 190BS of the bottom wafer 190, and an insulating layer 1090 is disposed adjacent to the chip pad 102. The bottom wafer 190 is then cut to become the first semiconductor chip 100.

The non-active surface 190BS of the bottom wafer 190 is prepared to be directed to face upward in the first direction (direction Y).

An adhesive layer 1600 is disposed between the carrier substrate 1500 and the bottom wafer 190 to fix the carrier substrate 1500 and the bottom wafer 190 to each other.

Referring back to FIG. 4, a plurality of first structures K, which are spaced apart from each other, are bonded onto the bottom wafer 190 (see S20).

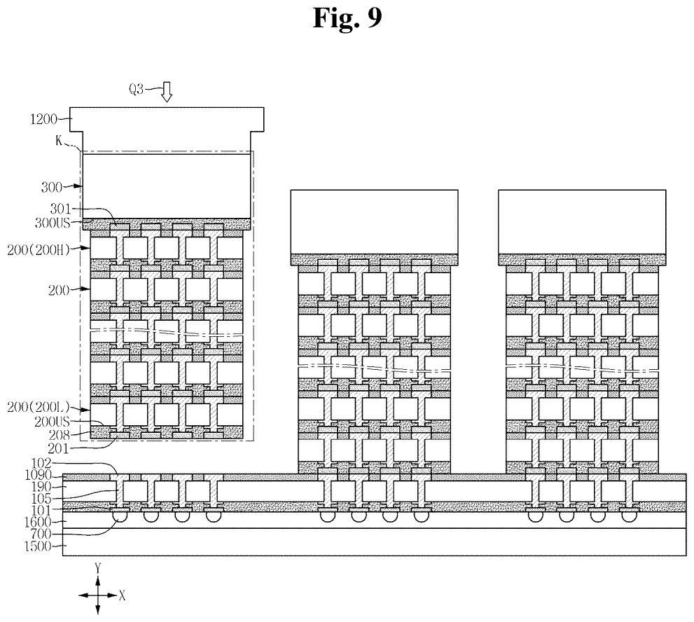

For example, referring to FIG. 9, the first structure K is picked up by using a bonding tool 1200 so that the first structure K is bonded to a preset position of the bottom wafer 190 (see reference numeral Q3).

For example, the bonding tool 1200 supports the bottom surface of the third semiconductor chip 300 of the first structure K, and bonds the first structure K to the bottom wafer 190 by turning the first structure K over. Therefore, the second semiconductor chip 200H, which is closest to the third semiconductor chip 300 in the chip structure 2000 when compared to the other second semiconductor chips 200, is positioned at the uppermost side with respect to the first direction (direction Y), and the second semiconductor chip 200L, which is farthest from the third semiconductor chip 300 in the chip structure 2000 when compared to the other second semiconductor chips 200, is positioned at the lowermost side in the first direction (direction Y). In addition, the third active surface 300US of the third semiconductor chip 300 and the second active surface 200US of the second semiconductor chip 200 are directed to face toward the bottom wafer 190.

The first structure K is bonded onto the bottom wafer 190 by hybrid bonding. For example, the chip pad 102 exposed at the bottom wafer 190 and the chip pad 201 exposed by the first structure K are directly connected to each other, and an insulating layer 1090 adjacent to the chip pad 102 that is exposed at the bottom wafer 190 and the insulating layer 208 adjacent to the chip pad 201 that is exposed at the first structure K are directly connected to each other.

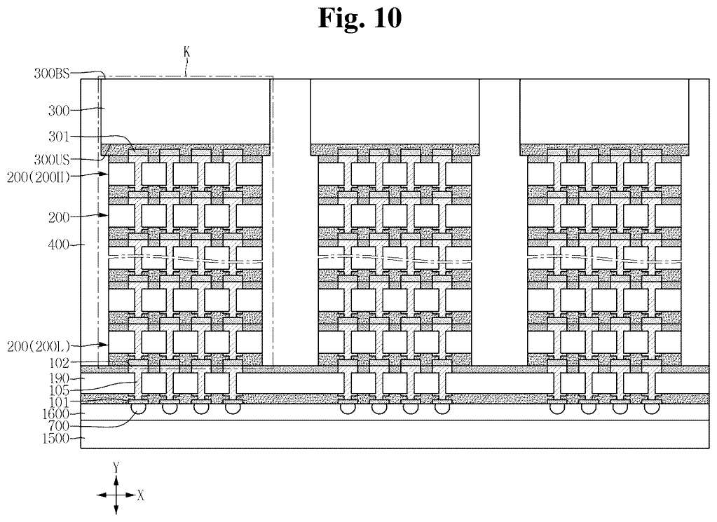

Subsequently, referring to FIG. 10, when a preset number of first structures K are all disposed on the bottom wafer 190, a mold material layer is formed on the bottom wafer 190 to cover the first structure K. Then, the mold material layer is removed so that the third non-active surface 300BS of the third semiconductor chip 300 is exposed, whereby a mold layer 400 filling a space between the adjacent first structures K is formed.

Referring back to FIG. 4, the bottom wafer 190 is cut for each of the plurality of first structures K to form a plurality of semiconductor packages (S30).

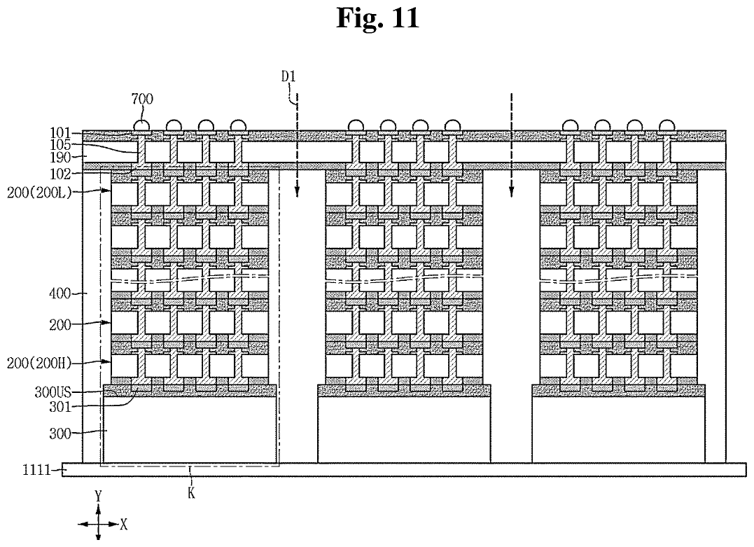

For example, referring to FIG. 11, the carrier substrate 1500 is separated by removing the adhesive layer 1600 from the structure of FIG. 10.

Subsequently, the structure of FIG. 10 from which the carrier substrate 1500 is removed is disposed on the support 1111. The mold layer 400, the bottom wafer 190 and the like are cut for each of the first structures K (see D1 of FIG. 11), so that a plurality of semiconductor packages are completed.

The completed semiconductor package is as shown in FIG. 1. The semiconductor package includes a first semiconductor chip (100 of FIG. 1), a plurality of second semiconductor chips 200 and a third semiconductor chip 300, which are sequentially stacked on the first semiconductor chip 100. In this case, the first semiconductor chip (sec 100 of FIG. 1) corresponds to the cut bottom wafer 190.

In summary, the plurality of second semiconductor chips 200 are stacked on the base wafer 390 that is relatively thick (see FIGS. 6 and 7). The base wafer 390 may be a wafer to which a thinning process for making a chip thickness thin is not applied. Therefore, even though the second semiconductor chip 200 is stacked on the base wafer 390, voids might not occur during chip stack.

On the other hand, when the plurality of second semiconductor chips 200 are sequentially stacked on the bottom wafer 190 that is thin, voids may occur during chip stack. This is because a thinning process is applied to the bottom wafer 190, so that a surface step difference is increased. In this case, deformation due to a bonding force is accompanied by a modulus of the adhesive layer 1600 (e.g., glue). As a result, as the plurality of second semiconductor chips 200 are stacked on the bottom wafer 190, an increase of the surface step difference in an upper layer of the plurality of second semiconductor chips 200 may be accumulated, resulting in occurrences of void defects during bonding.

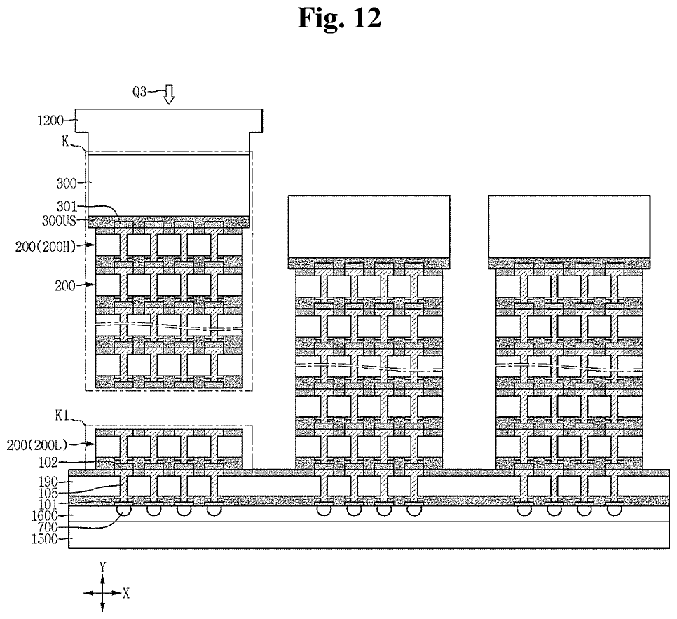

FIG. 12 is a view illustrating intermediate steps to describe a method for fabricating a semiconductor package according to embodiments of the present inventive concept. For convenience of description, the following description will be based on differences from the description made with reference to FIGS. 4 to 11.

According to the embodiment described with reference to FIGS. 4 to 11, all of the second semiconductor chips 200 belonging to the chip structure (see 2000 of FIG. 1) are stacked on the third semiconductor chip 300 (see FIG. 8) to complete the first structure K (sec FIG. 8), and the first structure K is bonded to the bottom wafer 190 to directly contact the bottom wafer 190 (see FIG. 9).

Referring to FIG. 12, only some second semiconductor chips 200 belonging to the chip structure (see 2000 of FIG. 1) are stacked on the third semiconductor chip 300 to complete the first structure K.

A second structure K1 in which the remaining second semiconductor chips 200 belonging to the chip structure 2000 are stacked is disposed on the bottom wafer 190. As shown, the second structure K1 may include at least one second semiconductor chip 200. However, the number of layers of the second semiconductor chips 200 belonging to the second structure K1 might not be affected by the modulus of the adhesive layer 1600 and the surface step difference of the bottom wafer 190.

Therefore, the first structure K is bonded to the second structure K1 corresponding thereto to directly contact the second structure K1 without being bonded to the bottom wafer 190 to directly contact the bottom wafer 190.

In addition, the semiconductor packages of FIGS. 2 and 3 may be fabricated in a manner substantially similar to that described with reference to FIGS. 4 to 11.

For example, when the second semiconductor chips 200 are disposed to be spaced apart from each other on the base wafer 390, and when the semiconductor package of FIG. 1 is fabricated, the second non-active surface 200BS of the second semiconductor chip 200 is bonded onto the base wafer 390 toward the active surface 390US of the base wafer 390 (see FIGS. 6 and 7). On the other hand, when the semiconductor package of FIG. 2 is fabricated, the second active surface 200US of the second semiconductor chip 200 may be bonded onto the base wafer 390 toward the active surface 390US of the base wafer 390.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package comprising:
a first semiconductor chip including a first substrate and a first through electrode passing through the first substrate, wherein the first substrate has a first active surface and a first non-active surface;
a chip structure including a plurality of second semiconductor chips stacked on the first semiconductor chip, wherein each second semiconductor chip includes a second substrate and a second through electrode passing through the second substrate, wherein the second substrate has a second active surface and a second non-active surface; and
a third semiconductor chip disposed on the chip structure, and including a third substrate having a third active surface and a third non-active surface,
wherein the first substrate has a first width and a first thickness, wherein the second substrate has a second width and a second thickness, and the third substrate has a third width and a third thickness,
wherein the third thickness is thicker than the second thickness, and the third width is greater than the second width.

2. The semiconductor package of claim 1, wherein the third thickness is thicker than the first thickness, and the third width is smaller than the first width.

3. The semiconductor package of claim 1, wherein an edge of the third semiconductor chip protrudes farther in a horizontal direction than a corresponding edge of a second semiconductor chip, of the plurality of second semiconductor chips, disposed at an uppermost side of the chip structure.

4. The semiconductor package of claim 3, wherein a distance between the edge of the third semiconductor chip and the corresponding edge of the second semiconductor chip that is disposed at the uppermost side of the chip structure is about 20 μm or more.

5. The semiconductor package of claim 1, wherein the plurality of second semiconductor chips and the third semiconductor chip are memory chips.

6. The semiconductor package of claim 5, wherein a remaining scribe line region of the third semiconductor chip is wider than a remaining scribe line region of the second semiconductor chip.

7. The semiconductor package of claim 1, wherein the third substrate includes silicon, and the third thickness is about 150 μm or more.

8. The semiconductor package of claim 1, wherein the second semiconductor chip is a memory chip, and the third semiconductor chip is a dummy chip.

9. The semiconductor package of claim 1, wherein a chip pad of a second semiconductor chip, of the plurality of second semiconductor chips, that is disposed at a lowermost side of the chip structure and a chip pad of the first semiconductor chip are coupled to each other, and an insulating layer, which is adjacent to the chip pad of the second semiconductor chip that is disposed at the lowermost side of the chip structure, and an insulating layer, which is adjacent to the chip pad of the first semiconductor chip, are coupled to each other.

10. The semiconductor package of claim 1, wherein chip pads of the plurality of second semiconductor chips face each other in the chip structure and are coupled to each other, and insulating layers that are adjacent to the chip pads of the second semiconductor chip face each other and are coupled to each other.

11. The semiconductor package of claim 1, wherein each of the second active surface and the third active surface face toward the first semiconductor chip.

12. The semiconductor package of claim 1, wherein each of the second non-active surface and the third active surface faced toward the first semiconductor chip.

13. The semiconductor package of claim 1, further comprising a mold layer at least partially surrounding a side of the chip structure and a side of the third semiconductor chip and exposing a side of the first semiconductor chip and an upper surface of the third semiconductor chip.

14. A semiconductor package comprising:
a first semiconductor chip including a first substrate, which has a first active surface and a first non-active surface, a first through electrode passing through the first substrate, a first chip pad disposed on the first active surface, a second chip disposed on the first non-active surface, and a first insulating layer at least partially surrounding a periphery of the second chip pad, wherein the first chip pad and the second chip pad are connected to each other through the first through electrode;
a chip structure including a plurality of second semiconductor chips stacked on the first semiconductor chip, wherein each second semiconductor chip includes a second substrate, which has a second active surface and a second non-active surface, a second through electrode passing through the second substrate, a third chip pad disposed on the second active surface, a fourth chip pad disposed on the second non-active surface, a second insulating layer at least partially surrounding a periphery of the third chip pad, and a third insulating layer at least partially surround a periphery of the fourth chip pad, wherein the third chip and the fourth chip pad are electrically connected to the second through electrode; and
a third semiconductor chip disposed on the chip structure, and including a third substrate, which has a third active surface and a third non-active surface, a fifth chip pad disposed on the third active surface, and a fourth insulating layer at least partially surrounding a periphery of the third chip pad,
wherein the third chip pad of a second semiconductor chip, of the plurality of second semiconductor chips, disposed at a lowermost side of the chip structure and the second chip pad of the first semiconductor chip are coupled to each other, and a second insulating layer of the second semiconductor chip that is disposed at the lowermost side of the chip structure and the first insulating layer of the first semiconductor chip are coupled to each other,
wherein a third chip pad of a second semiconductor chip, of the plurality of second semiconductor chips, that is disposed at an uppermost side of the chip structure and the fourth chip pad of the third semiconductor chip are coupled to each other, and a third insulating layer of the second semiconductor chip that is disposed at the uppermost side of the chip structure and the fourth insulating layer of the third semiconductor chip are coupled to each other,
wherein the first substrate has a first width and a first thickness, wherein the second substrate has a second width and a second thickness, and the third substrate has a third width and a third thickness,
wherein the third thickness is thicker than the second thickness, and the third width is greater than the second width, and
the third thickness is thicker than the first thickness, and the third width is smaller than the first width.

15. A method for fabricating a semiconductor package, the method comprising:
preparing a first structure including a third semiconductor chip and a plurality of second semiconductor chips stacked on the third semiconductor chip;
bonding a plurality of the first structures, which are spaced apart from each other, onto a bottom wafer; and
forming a plurality of semiconductor packages by cutting the bottom wafer for each of the plurality of first structures, wherein each of the plurality of semiconductor packages includes a first semiconductor chip, the plurality of second semiconductor chips stacked on the first semiconductor chip, and the third semiconductor chip stacked on the plurality of second semiconductor chips, and wherein the first semiconductor chip corresponds to the bottom wafer that is cut,
wherein a first substrate of the first semiconductor chip has a first width and a first thickness, wherein a second substrate of each of the plurality of second semiconductor chips has a second width and a second thickness, and a third substrate of the third semiconductor chip has a third width and a third thickness, and
the third thickness is thicker than the second thickness, and the third width is greater than the second width.

16. The method of claim 15, wherein the third thickness is thicker than the first thickness, and the third width is smaller than the first width.

17. The method of claim 15, wherein each of the plurality of second semiconductor chips and the third semiconductor chip is a memory chip, and
each of the plurality of second semiconductor chips is a chip that is cut with a blade dicing manner, and the third semiconductor chip is a chip that is cut with a stealth dicing manner.

18. The method of claim 15, wherein the bonding the plurality of the first structures onto the bottom wafer includes:
directly connecting a chip pad disposed on the bottom wafer with a chip pad disposed on the first structure; and
directly connecting an insulating layer, which is adjacent to the chip pad that is disposed on the bottom wafer, with an insulating layer, which is adjacent to the chip pad that is disposed on the first structure.

19. The method of claim 15, wherein the preparing a first structure includes that a third active surface of the third semiconductor chip is directed to face toward the second semiconductor chip, and a second non-active surface of each of the plurality of second semiconductor chips is directed to face toward the third semiconductor chip.

20. The method of claim 15, further comprising bonding a plurality of second structures onto the bottom wafer, wherein the plurality of second structures are spaced apart from each other, and includes a second semiconductor chip of at least one layer,
wherein the bonding the plurality of the first structures onto the bottom wafer includes bonding each of the plurality of first structures onto a corresponding one of the plurality of second structures.
